(19) United States
(12) Patent Application Publication
(10) Pub. No.: US 2020/0090564 A1
(43) Pub. Date: Mar. 19, 2020

(54) DISPLAY PANEL AND METHOD FOR DETECTING DISPLAY PANEL

(71) Applicant: WUHAN CHINA STAR OPTOELECRTRONICS TECHNOLOGY CO., LTD., Wuhan, Hubei (CN)

(72) Inventors: Yaoli HUANG, Wuhan, Hubei (CN); Xinglong HE, Wuhan, Hubei (CN)

(21) Appl. No.: 16/338,436

(22) PCT Filed: Jan. 14, 2019
(86) PCT No.: PCT/CN2019/071656

§ 371 Date: Mar. 29, 2019

(30) Foreign Application Priority Data
Aug. 30, 2018 (CN) 201810999209.1

(51) Int. Cl. G09G 3/00; H04N 9/31; G01R 27/14

(52) U.S. Cl. CPC G09G 3/006; G01R 27/14; H04N 9/3191

(57) ABSTRACT

A display panel includes a glass substrate having a display area and a non-display area. The non-display area is defined on an outermost area of the glass substrate. A display chip is disposed on the non-display area and functions as a driving element of the display panel. A testing metal line is disposed on the non-display area and wound along the non-display area. The testing metal line starts with a first test point and ends with a second test point, and the first test point and the second point are not connected with each other to form an open circuit. The first test point and the second test point are configured to electrically connect to an external resistance test instrument to detect a resistance value of the test metal line.

### BACKGROUND OF INVENTION

### 1. Field of Invention

The present invention relates to a technical field of displays, and particularly to a method for detecting whether a display panel glass has cracks and a display panel.

### 2. Related Art

Display panels are composed of upper and lower glass substrates. In order to detect function of various components of the product and confirm failure of each component, the display panel is usually subjected to various mechanical tests.

During manufacturing processes of the display panels, such as the splitting or assembly process, the problem that cracks are formed in the glass substrates may arise from various manufacturing processes. Additionally, the display panels are required to go through a variety of mechanical tests after being finished, and such mechanical tests are also likely to give rise to the formation of cracks. Therefore, prior to being presented to clients, the display panels must be checked first. Generally, with respect to a mechanical test of 4PB (four-point-bending test), drop, vibration, etc., display images of display panels are to be tested after the mechanical tests, wherein the mechanical tests are determined to be passed if there is no abnormality in the display images. If the display images are abnormal, it is to say that lines are damaged by the drop test, and the mechanical test is not passed. However, slight cracks are formed on borders of glass substrates of display panels in some cases, and such slight cracks do not cause serious damage on lines, and display panels still can operate normally. However, during subsequent use, slight cracks may gradually expand, so that part of the lines on the glass substrates is completely broken, causing abnormally display.

### SUMMARY OF INVENTION

An object of the present invention is to provide a method for detecting a display panel and a display panel which is capable of precisely and effectively detecting whether the display panel has cracks, thereby to realize crack detection without disassembling, improve the detection efficiency, and avoid a risk of inadvertently providing defective products to the client.

To achieve the above-mentioned object, a display panel comprises a glass substrate, comprising a display area and a non-display area, the display area configured to display images, and the non-display area defined on an outermost area of the glass substrate; a display chip, disposed on the non-display area and functioning as a driving element of the display panel; and a testing metal line, disposed on the non-display area and wound along the non-display area, the testing metal line starting with a first test point and ending with a second test point, wherein the first test point and the second point are not connected with each other to form an open circuit, and the first test point and the second test point are configured to electrically connect to an external resistance test instrument to detect a resistance value of the test metal line.

In one aspect of the present invention, the glass substrate comprises an upper color film substrate and a lower thin-film transistor (TFT) array substrate, the TFT array substrate comprises a base substrate, a functional layer is disposed on the base substrate, a lip portion is disposed between an edge portion of the color film substrate and an edge portion of the TFT array substrate, and an exposed groove is disposed on the functional layer corresponding to the lip portion, and wherein the first test point and the second test point of the testing metal line are located beneath the groove.

In one aspect of the present invention, the display panel further comprises a transparent conductive film layer disposed on the first test point and the second test point of the testing metal line and extending to two opposite sides of the groove.

In one aspect of the present invention, the functional layer comprises a lower insulating layer, a gate insulating layer, an interlayer dielectric layer, a flat layer, an upper insulating layer, and a passivation layer, wherein a frame sealing glue is provided on the passivation layer, and the color film substrate is adhered to the frame sealing glue, and wherein the groove penetrates the passivation layer, the upper insulating layer, the flat layer, and the interlayer dielectric layer, and the testing metal line is disposed on the gate insulating layer.

In one aspect of the present invention, the testing metal line is located beneath the display chip and penetrates a region located right below the display chip.

In one aspect of the present invention, the non-display area of the glass substrate encapsulates the display area and comprises an upper border portion and a lower border portion, and the first test point and the second test point of the test metal line are disposed at a position corresponding to the upper border portion or the lower border portion.

In one aspect of the present invention, the resistance value of the testing metal line comprises a first resistance value and a second resistance value, the second resistance value is obtained after the display panel is mechanically tested, and the first resistance value is obtained before the display panel is mechanically tested, wherein when the second resistance value exceeds the first resistance value by a predetermined range, the glass substrate of the display panel is determined to be a substrate having cracks.

The present invention further provides a method for detecting a display panel, the method comprising defining a display area and a non-display area on a glass substrate, the display area configured to display images, and the non-display area defined on an outermost area of the glass substrate; providing a display chip on the non-display area; depositing a testing metal line on the non-display area, the testing metal line wound along the non-display area, wherein the testing metal line starts with a first test point and ends with a second test point, and the first test point and the second point are not connected with each other to form an open circuit; and connecting the first test point and the second point to an external resistance test instrument to detect a resistance value of the test metal line.

In one aspect of the present invention, the glass substrate comprises an upper color film substrate and a lower thin-film transistor (TFT) array substrate, the TFT array substrate comprises base substrate, a functional layer is disposed on the base substrate, a lip portion is disposed between an edge portion of the color film substrate and an edge portion of the TFT array substrate, and an exposed groove is disposed on the functional layer corresponding to the lip portion, and wherein the first test point and the second test point of the testing metal line are located beneath the groove.

In one aspect of the present invention, the display panel is performed with a mechanical test, and prior to performing the mechanical test, detects the resistance value of the test metal line by electrically connecting the external resistance test instrument to the first test point and the second point to obtain a first resistance value, wherein after the display panel is mechanically tested, obtains, through the external resistance test instrument, a second resistance value, and when the second resistance value exceeds the first resistance value by a predetermined range, the glass substrate of the display panel is determined to be a substrate having cracks.

In one aspect of the present invention, the display panel further comprises a transparent conductive film layer disposed on the first test point and the second test point of the testing metal line and extending to two opposite sides of the groove.

The present invention further provides a display panel, comprising a glass substrate, comprising a display area and a non-display area, the display area configured to display images, and the non-display area defined on an outermost area of the glass substrate; a display chip, disposed on the non-display area and functioning as a driving element of the display panel; and a testing metal line, disposed on the non-display area and wound along the non-display area, the testing metal line starting with a first test point and ending with a second test point, wherein the first test point and the second point are not connected with each other to form an open circuit, and the first test point and the second test point are configured to electrically connect to an external resistance test instrument to detect a resistance value of the test metal line, wherein the glass substrate comprises an upper color film substrate and a lower thin-film transistor (TFT) array substrate, the TFT array substrate comprises a base substrate, a functional layer is disposed on the base substrate, a lip portion is disposed between an edge portion of the color film substrate and an edge portion of the TFT array substrate, and an exposed groove is disposed on the functional layer corresponding to the lip portion and penetrates in a direction towards the color film substrate, and wherein the first test point and the second test point of the testing metal line are located beneath the groove.

In one aspect of the present invention, the display panel further comprises a transparent conductive film layer disposed on the first test point and the second test point of the testing metal line and extending to two opposite sides of the groove.

In one aspect of the present invention, the testing metal line is disposed located beneath the display chip and penetrates a region located right below the display chip.

In one aspect of the present invention, the resistance value of the testing metal line comprises a first resistance value and a second resistance value, the second resistance value is obtained after the display panel is mechanically tested, and the first resistance value is obtained before the display panel is mechanically tested, wherein when the second resistance value exceeds the first resistance value by a predetermined range, the glass substrate of the display panel is determined to be a substrate having cracks.

The present invention utilizes the open circuit of the testing metal line disposed on the outermost periphery of the glass substrate to connect with the external resistance test instrument after a finished product of the display panel undergoes the mechanical tests. By connecting the external resistance test instrument to the first test point 31 and the second test point 32 to detect variation of the resistance value of the testing metal line 3, the present invention is capable of detecting whether the glass substrate of the display panel has slight cracks without disassembling, thereby effectively overcoming the inconvenience that traditional display panels are required to be disassembled first to detect cracks, and avoiding a problem that defective products are inadvertently provided to clients because of imprecisely examination of cracks formed on the glass substrate.

### BRIEF DESCRIPTION OF DRAWINGS

FIG. 1 is a schematic structural view of a display panel in accordance with an embodiment of the present invention.

FIG. 2 is a schematic cross-sectional view of a display panel in accordance with an embodiment of the present invention.

FIG. 3 is a schematic structural view of a display panel in accordance with an embodiment of the present invention.

FIG. 4 is a schematic structural view of a display panel in accordance with an embodiment of the present invention.

FIG. 5 is a partially schematic structural view of a display panel in accordance with an embodiment of the present invention.

FIG. 6 is a flowchart of a method for detecting a display panel of the present invention.

### DESCRIPTION OF PREFERRED EMBODIMENTS

The following embodiments are referring to the accompanying drawings for exemplifying specific implementable embodiments of the present disclosure. Furthermore, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, elements with similar structures are labeled with like reference numerals.

The present invention discloses a display panel and a method for detecting the display panel. The display panel, for example, is a display panel embedded with a touch panel circuit, and the testing method is capable of precisely detecting whether a finished product of the display panel has cracks without disassembling.

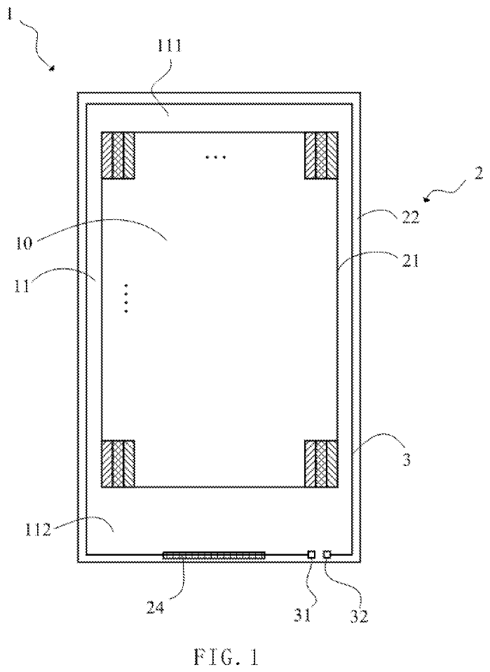

FIG. 1 is a schematic structural view of a display panel in accordance with an embodiment of the present invention. As shown in FIG. 1, a display panel 1 of the present invention includes a glass substrate 2 having a display area 10 and a non-display area 11. The non-display area 11 is defined on an outermost area of the glass substrate 2, that is, the non-display area 11 encapsulates the display area 10. The non-display area 11 includes an upper border portion 111 and a lower border portion 112. The display area 10 is an area of the display panel 1 displaying images. Furthermore, a display chip 24 is disposed on the glass substrate 2 functioning as a driving element of the display panel 1.

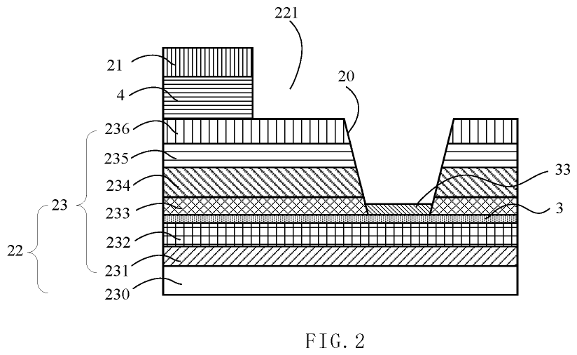

FIG. 2 is a schematic cross-sectional view of a display panel in accordance with an embodiment of the present invention. As shown in FIG. 2, the glass substrate 2 includes an upper color film substrate 21 and a lower thin-film transistor (TFT) array substrate 22. The TFT array substrate 22 includes a base substrate 230, and a functional layer 23 is disposed on the base substrate 230. The functional layer 23 includes, from a lower to a top of the functional layer 23, a lower insulating layer 231, a gate insulating layer 232, an interlayer dielectric layer 233, a flat layer 234, an upper insulating layer 235, and a passivation layer 236, wherein a frame sealing glue 4 is provided on the passivation layer 236, and the color film substrate 21 is adhered to the frame sealing glue 4. Furthermore, the color film substrate 21 and the TFT array substrate 22 each has portions corresponding to the display area 10 and the non-display area 11.

Particularly, a lip portion 231 is disposed between an edge portion of the color film substrate 21 and an edge portion of the TFT array substrate 22. An exposed groove 20 is disposed on the functional layer 23 corresponding to the lip portion 221. Specifically, the groove 20 penetrates the passivation layer 236, the upper insulating layer 235, the flat layer 234, and the interlayer dielectric layer 233 through an etching process. In other words, the groove 20 penetrates in a direction towards the color film substrate 21 and is exposed outside.

Please continuously refer to FIG. 1. The display panel 1 of the present invention includes a testing metal line 3. The testing metal line 3 is disposed on the non-display area 11 and is wound along the non-display area 11. The testing metal line 3 starts with a first test point 31 and ends with a second test point 32, wherein the first test point 31 and the second point 32 are not connected with each other to form an open circuit. In this embodiment, the first test point 31 and the second point 32 are located at a right side of the lower border portion 112 of the non-display area 11. Specifically, the testing metal line 3 is not connected with other internal components of the display panel 1 to avoid affecting a resistance test result when the testing metal line 3 is connected to an external resistance test instrument (not shown).

Please continuously refer to FIG. 2. The testing metal line 3 is disposed on the gate insulating layer 232, and the first test point 31 and the second test point 32 are located beneath the groove 20 and exposed to the lip portion 221. Furthermore, to avoid a risk that the exposed testing metal line 3 is corroded, a transparent conductive film layer 33 is disposed on the first test point 31 and the second test point 32 and extends to two opposite sides of the groove 20. The transparent conductive film layer 33 is made of indium tin oxide.

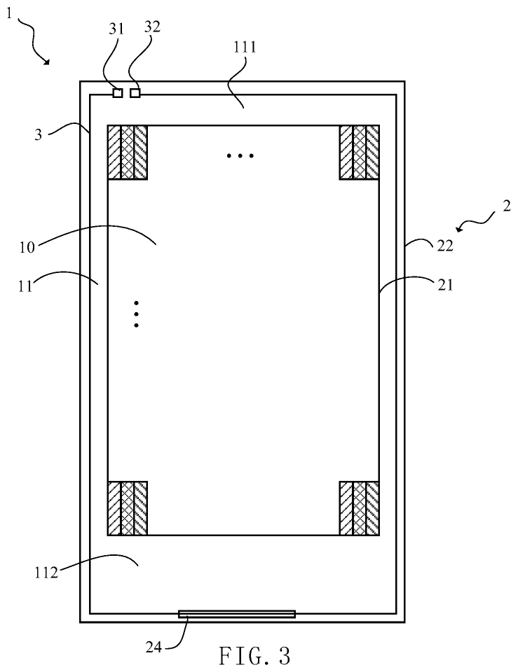

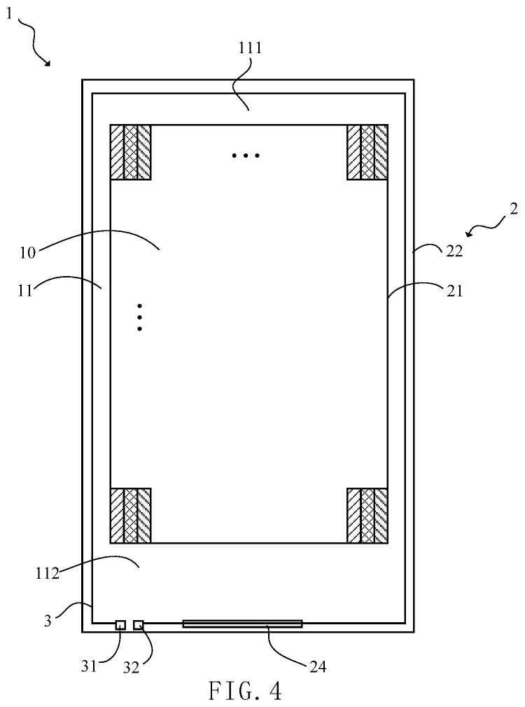

FIGS. 3 and 4 are schematic structural views of a display panel in accordance with an embodiment of the present invention. As shown in FIG. 3, the first test point 31 and the second test point 32 of the testing metal line 3 are located at a right side of the upper border portion 111 of the non-display area 11. As shown in FIG. 4, the first test point 31 and the second test point 32 of the testing metal line 3 are located at a left side of the lower border portion 112 of the non-display area 11. Set positions of the first test point 31 and the second test point 32 are varied according to types of external resistance test instruments.

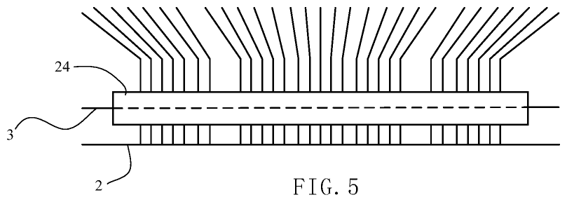

FIG. 5 is a partially schematic structural view of a display panel in accordance with an embodiment of the present invention. Because the display chip 24 is located at an outermost periphery of the display area 1 and upper and lower portions of the display chip 24 are filled with wires, the only space allowed to accommodate the testing metal line 3 is right below the display chip 24. Accordingly, the testing metal line 3 is located beneath the display chip 24 and penetrates a region located right below the display chip 24. In this manner, the layout of the testing metal line 3 does not take up additional space inside the glass substrate 2.

Generally, prior to providing finish products of display panels to clients, the display panels will be checked first through various mechanical tests, for example, such as 4PB (four-point-bending test), drop, vibration, etc., to test whether display images are normal. However, normal display images cannot assure that there are no cracks formed in glass substrates. The display panel 1 of the present invention in a finished product phase, prior to undergoing mechanical tests, is first to be detected for a resistance value of the testing metal line 3 by the external resistance test instrument. A first resistance value is obtained by directly and electrically connecting two test leads of the external resistance test instrument to the first test point 31 and the second test point 32 of the test metal line 3, respectively. The first resistance value is a standard value. A second resistance value is obtained after the display panel 1 undergoes the mechanical tests. After the mechanical tests, positions where cracks are most likely to form are at outmost peripheries of the glass substrate 2. The cracks will damage the testing metal line 3 and change a resistance value of the testing metal line 3. When the second resistance value exceeds the first resistance value by 10%, the glass substrate 2 of the display panel 1 is determined to be a substrate having cracks.

In another embodiment, differences in thickness of the testing metal line will also affect test results. Finer cracks can give rise to a large effect on the resistance of thin testing metal lines, but have less effect on the resistance of thick testing metal lines. Therefore, thin metal wires are used when it is necessary to detect fine cracks, and thick metal wires are required for detecting large cracks, depending on practical situations.

The present invention utilizes the open circuit of the testing metal line disposed on the outermost periphery of the glass substrate to connect with the external resistance test instrument after a finished product of the display panel undergoes the mechanical tests. By connecting the external resistance test instrument to the first test point 31 and the second test point 32 to detect variation of the resistance value of the testing metal line 3, the present invention is capable of detecting whether the glass substrate of the display panel has slight cracks without disassembling, thereby effectively overcoming the inconvenience that traditional display panels are required to be disassembled first to detect cracks, and avoiding a problem that defective products are inadvertently provided to clients because of imprecisely examination of cracks formed on the glass substrate.

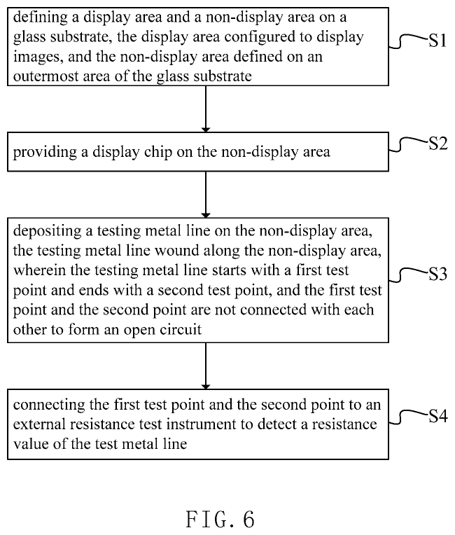

The present invention further provides a method for detecting a display panel. FIG. 6 is a flowchart of a method for detecting a display panel of the present invention. As shown in FIG. 6, the method for detecting the display panel of the present invention includes: step S1: defining a display area and a non-display area on a glass substrate, the display area configured to display images, and the non-display area defined on an outermost area of the glass substrate.

Step S2: providing a display chip on the non-display area.

Step S3: forming a testing metal line by physical vapor deposition on the non-display area, the testing metal line wound along the non-display area, wherein the testing metal line starts with a first test point and ends with a second test point, and the first test point and the second point are not connected with each other to form an open circuit.

Step S4: connecting the first test point and the second point to an external resistance test instrument to detect a resistance value of the test metal line.

In a practical test, the display panel is performed with a mechanical test, and prior to performing the mechanical test, detects the resistance value of the test metal line by electrically connecting the external resistance test instrument to the first test point and the second point to obtain a first resistance value, wherein after the display panel is mechanically tested, obtains, through the external resistance test instrument, a second resistance value, and wherein when the second resistance value exceeds the first resistance value by a predetermined range, the glass substrate of the display panel is determined to be a substrate having cracks.

Specifically, the glass substrate comprises an upper color film substrate and a lower thin-film transistor (TFT) array substrate, the TFT array substrate comprises a base substrate, a functional layer is disposed on the base substrate, a lip portion is disposed between an edge portion of the color film substrate and an edge portion of the TFT array substrate, and an exposed groove is disposed on the functional layer corresponding to the lip portion, and wherein the first test point and the second test point of the testing metal line are located beneath the groove. In other words, the two test leads of the external resistance test instrument are probed into the groove to directly and electrically contact the first test point and the second test point, respectively, to obtain the first resistance value and the second resistance value, thereby the resistance value of the testing metal line can be directly detected without disassembling the display panel.

Furthermore, a transparent conductive film layer disposed on the first test point and the second test point of the testing metal line and extending to two opposite sides of the groove.

The structure of the display panel used in the method for detecting the display panel of the present invention is same as the structure of the display panel of the foregoing embodiments, and details are not described herein again.

Accordingly, although the present invention has been disclosed as a preferred embodiment, it is not intended to limit the present invention. Those skilled in the art without departing from the spirit and scope of the present invention may make various changes or modifications, and thus the scope of the present invention should be after the appended claims and their equivalents.

What is claimed is:

1. A display panel, comprising:
a glass substrate comprising a display area and a non-display area, the display area configured to display images, and the non-display area defined on an outermost area of the glass substrate;
a display chip disposed on the non-display area and functioning as a driving element of the display panel; and
a testing metal line disposed on the non-display area and wound along the non-display area, the testing metal line starting with a first test point and ending with a second test point, wherein the first test point and the second point are not connected with each other to form an open circuit, and the first test point and the second test point are configured to electrically connect to an external resistance test instrument to detect a resistance value of the test metal line.

2. The display panel of claim 1, wherein the glass substrate comprises an upper color film substrate and a lower thin-film transistor (TFT) array substrate, the TFT array substrate comprises a base substrate, a functional layer is disposed on the base substrate, a lip portion is disposed between an edge portion of the color film substrate and an edge portion of the TFT array substrate, and an exposed groove is disposed on the functional layer corresponding to the lip portion, and wherein the first test point and the second test point of the testing metal line are located beneath the groove.

3. The display panel of claim 2, further comprising a transparent conductive film layer disposed on the first test point and the second test point of the testing metal line and extending to two opposite sides of the groove.

4. The display panel of claim 2, wherein the functional layer comprises a lower insulating layer, a gate insulating layer, an interlayer dielectric layer, a flat layer, an upper insulating layer, and a passivation layer, wherein a frame sealing glue is provided on the passivation layer, and the color film substrate is adhered to the frame sealing glue, and wherein the groove penetrates the passivation layer, the upper insulating layer, the flat layer, and the interlayer dielectric layer, and the testing metal line is disposed on the gate insulating layer.

5. The display panel of claim 1, wherein the testing metal line is located beneath the display chip and penetrates a region located right below the display chip.

6. The display panel of claim 1, wherein the non-display area of the glass substrate encapsulates the display area and comprises an upper border portion and a lower border portion, and the first test point and the second test point of the test metal line are disposed at a position corresponding to the upper border portion or the lower border portion.

7. The display panel of claim 1, wherein the resistance value of the testing metal line comprises a first resistance value and a second resistance value, the second resistance value is obtained after the display panel is mechanically tested, and the first resistance value is obtained before the display panel is mechanically tested, wherein when the second resistance value exceeds the first resistance value by a predetermined range, the glass substrate of the display panel is determined to be a substrate having cracks.

8. A method for detecting a display panel, comprising:
defining a display area and a non-display area on a glass substrate, the display area configured to display images, and the non-display area defined on an outermost area of the glass substrate;
providing a display chip on the non-display area;
depositing a testing metal line on the non-display area, the testing metal line wound along the non-display area, wherein the testing metal line starts with a first test point and ends with a second test point, and the first test point and the second point are not connected with each other to form an open circuit; and
connecting the first test point and the second point to an external resistance test instrument to detect a resistance value of the test metal line.

9. The method for detecting the display panel of claim 8, wherein the glass substrate comprises an upper color film substrate and a lower thin-film transistor (TFT) array substrate, the TFT array substrate comprises a base substrate, a functional layer is disposed on the base substrate, a lip portion is disposed between an edge portion of the color film substrate and an edge portion of the TFT array substrate, and an exposed groove is disposed on the functional layer corresponding to the lip portion, and wherein the first test point and the second test point of the testing metal line are located beneath the groove.

10. The method for detecting the display panel of claim 8, wherein the display panel is performed with a mechanical test, and prior to performing the mechanical test, detects the resistance value of the test metal line by electrically connecting the external resistance test instrument to the first test point and the second point to obtain a first resistance value, wherein after the display panel is mechanically tested, obtains, through the external resistance test instrument, a second resistance value, and when the second resistance value exceeds the first resistance value by a predetermined range, the glass substrate of the display panel is determined to be a substrate having cracks.

11. The method for detecting the display panel of claim 9, further comprising a transparent conductive film layer disposed on the first test point and the second test point of the testing metal line and extending to two opposite sides of the groove.

12. A display panel, comprising:
a glass substrate, comprising a display area and a non-display area, the display area configured to display images, and the non-display area defined on an outermost area of the glass substrate;
a display chip, disposed on the non-display area and functioning as a driving element of the display panel; and
a testing metal line, disposed on the non-display area and wound along the non-display area, the testing metal line starting with a first test point and ending with a second test point, wherein the first test point and the second point are not connected with each other to form an open circuit, and the first test point and the second test point are configured to electrically connect to an external resistance test instrument to detect a resistance value of the test metal line,
wherein the glass substrate comprises an upper color film substrate and a lower thin-film transistor (TFT) array substrate, the TFT array substrate comprises a base substrate, a functional layer is disposed on the base substrate, a lip portion is disposed between an edge portion of the color film substrate and an edge portion of the TFT array substrate, and an exposed groove is disposed on the functional layer corresponding to the lip portion and penetrates in a direction towards the color film substrate, and wherein the first test point and the second test point of the testing metal line are located beneath the groove.

13. The display panel of claim 12, further comprising a transparent conductive film layer disposed on the first test point and the second test point of the testing metal line and extending to two opposite sides of the groove.

14. The display panel of claim 12, wherein the testing metal line is disposed located beneath the display chip and penetrates a region located right below the display chip.

15. The display panel of claim 12, wherein the resistance value of the testing metal line comprises a first resistance value and a second resistance value, the second resistance value is obtained after the display panel is mechanically tested, and the first resistance value is obtained before the display panel is mechanically tested, wherein when the second resistance value exceeds the first resistance value by a predetermined range, the glass substrate of the display panel is determined to be a substrate having cracks.
